(19) United States
(12) Patent Application Publication
(10) Pub. No.: US 2025/0385686 A1
(43) Pub. Date: Dec. 18, 2025

(54) Digital Transmitter

(71) Applicant: QUALCOMM Incorporated, San Diego, CA (US)

(72) Inventor: Edward Wai Yeung LIU, San Diego, CA (US)

(21) Appl. No.: 18/745,809

(22) Filed: Jun. 17, 2024

(51) Int. Cl. H03M 1/74

(52) U.S. Cl. CPC H03M 1/74

(57) ABSTRACT

Certain aspects of the present disclosure provide a radio frequency (RF) digital transmitter. An example a RF transmitter includes a multi-order hold digital-to-analog converter (DAC) configured to output a signal with a carrier frequency in a radio frequency (RF) bandwidth, the multi-order hold DAC comprising: a first DAC and a second DAC. The RF transmitter further includes one or more reference voltage generators coupled to the multi-order hold DAC, wherein the one or more reference voltage generators are configured to feed a first reference voltage to the first DAC and feed a second reference voltage to the second DAC, and wherein the one or more reference voltage generators are configured to output the first reference voltage with a first time-varying voltage across a symbol period.

### INTRODUCTION

### Field of the Disclosure

Aspects of the present disclosure relate to a transmitter, and more particularly, to a digital radio frequency (RF) transmitter.

### Description of Related Art

Wireless communications systems are widely deployed to provide various telecommunication services such as telephony, video, data, messaging, broadcasts, etc. These wireless communications systems may employ multiple-access technologies capable of supporting communications with multiple users by sharing available wireless communications system resources with those users. Wireless communication devices may communicate RF signals via any of various suitable radio access technologies (RATs) including, but not limited to, 5G New Radio (NR), Evolved Universal Terrestrial Radio Access (E-UTRA), Code Division Multiple Access (CDMA), Time Division Multiple Access (TDMA), Wideband CDMA (WCDMA), Global System for Mobility (GSM), Bluetooth, Bluetooth Low Energy (BLE), ZigBee, wireless local area network (WLAN) RATs (e.g., Institute of Electrical and Electronics Engineers (IEEE) 802.11 specifications), any future RAT, and/or the like.

In certain cases, a wireless communications device is equipped with an RF transceiver (also referred to as an RF front-end) for communicating RF signals. In general, a baseband signal is modulated to convey information using a modulation technique, such as phase-shift keying (PSK) or any other suitable modulation technique. In a transmit mode, the RF transceiver is responsible for multiplexing the baseband signal with an RF carrier signal that is transmitted over the air (e.g., a wireless communication channel). Such an operation is called upconversion. In a receive mode, the RF transceiver converts a received RF signal to the baseband signal. Such an operation is called downconversion. The received baseband signal then can be demodulated into the information encoded at a transmitter. The RF transceiver may include a cascade of components in a transmit chain and a receive chain, respectively. The cascade of components may include, for example, one or more of attenuators, switches, couplers, filters, mixers, amplifiers, frequency synthesizers, oscillators, antenna tuners, duplexers, diplexers, detectors, etc.

Although there have been great technological advancements in RF circuitry over many years, challenges still exist. For example, RF circuitry can still encounter image(s) in signals generated through digital-to-analog conversion. Accordingly, there is a continuous desire to improve the technical performance of RF circuitry, such as image suppression and/or elimination.

### SUMMARY

Some aspects provide a radio frequency (RF) transmitter. The RF transmitter includes a multi-order hold digital-to-analog converter (DAC) configured to output a signal with a carrier frequency in a radio frequency (RF) bandwidth, the multi-order hold DAC comprising: a first DAC and a second DAC. The RF transmitter further includes one or more reference voltage generators coupled to the multi-order hold DAC, wherein the one or more reference voltage generators are configured to feed a first reference voltage to the first DAC and feed a second reference voltage to the second DAC, and wherein the one or more reference voltage generators are configured to output the first reference voltage with a first time varying voltage across a symbol period.

Some aspects provide a method of operating a radio frequency (RF) transmitter. The method includes providing, to a multi-order hold DAC, one or more digital signals associated with a signal with a carrier frequency in a radio frequency (RF) bandwidth, wherein the multi-order hold DAC comprises a first DAC and a second DAC. The method further includes providing, via one or more reference voltage generators, a first reference voltage to the first DAC and a second reference voltage to the second DAC, wherein the first reference voltage has a first time-varying voltage across a symbol period. The method further includes outputting the signal via the multi-order hold DAC.

Other aspects provide: an apparatus operable, configured, or otherwise adapted to perform any one or more of the aforementioned methods and/or those described elsewhere herein; a non-transitory, computer-readable medium comprising instructions that, when executed by a processor of an apparatus, cause the apparatus to perform the aforementioned methods as well as those described elsewhere herein; a computer program product embodied on a computer-readable storage medium comprising code for performing the aforementioned methods as well as those described elsewhere herein; and/or an apparatus comprising means for performing the aforementioned methods as well as those described elsewhere herein. By way of example, an apparatus may comprise a processing system, a device with a processing system, or processing systems cooperating over one or more networks.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the drawings. It is to be noted, however, that the appended drawings illustrate only certain typical aspects of this disclosure and are therefore not to be considered limiting of its scope, for the description may admit to other equally effective aspects.

FIG. 1 illustrates an example wireless communications system.

FIG. 2 illustrates an example wireless communications device communicating with another device.

FIG. 3 illustrates an example architecture for a digital radio frequency (RF) transmitter.

FIG. 4 depicts a graph of example envelopes for output signals of the digital transmitter of FIG. 3.

FIG. 5 depicts an example output stage of a digital-to-analog converter (DAC) of a multi-order hold DAC, for example, as described herein with respect to FIG. 3.

FIG. 6 illustrates an example method of operating an RF transmitter.

To facilitate understanding, identical reference numerals have been used, where possible, to designate identical elements that are common to the figures. It is contemplated that elements disclosed in one aspect may be beneficially utilized in other aspects without specific recitation.

### DETAILED DESCRIPTION

Aspects of the present disclosure provide apparatus, methods, processing systems, and computer-readable mediums for a radio frequency (RF) digital transmitter.

In certain cases, an RF transmitter may employ a digital-to-analog converter (DAC) to output a signal at an RF carrier frequency. The DAC may serve as a digital transmitter that converts a digital signal directly to an RF signal. The DAC may output the signal at the RF carrier frequency without using an upconversion stage, for example, that feeds a baseband signal to one or more upconversion mixers. Due to its RF output, the digital transmitter can reduce or eliminate certain components in a transmit chain, such as an amplifier, mixer, local oscillator, frequency synthesizer, bandpass filter, etc. The digital transmitter can reduce power consumption, for example, due to the reduction of certain components in the transmit chain. The digital transmitter can reduce or eliminate certain non-linear effects (e.g., harmonic distortion, gain compression, in- phase-quadrature mismatch, etc.) exhibited in a transmit chain, for example, due to the non-linear effects being attributable to certain components that can be removed, such as mixers and/or amplifiers.

Technical problems for a digital transmitter may include, for example, effective handling of image(s) generated by a DAC. In certain cases, the DAC may output the RF signal along with a residual image at a different frequency, for example, due to residual spectral components being present in the oscillating signal (e.g., the clock signal) that drives the DAC. The DAC may output an image in a frequency band offset from the center frequency of the carrier based on the sampling frequency applied to the DAC. For example, the image may be exhibited at a frequency of F_{c}+n*Fₛ, where F_{c} is the center frequency of the carrier, n is an integer, and Fₛ is the sampling or update frequency for the DAC. Thus, to suppress the image, the sampling frequency that drives the DAC may be increased to push the image outside the bandwidth of the RF carrier and enable the image to be suppressed from the DAC output via filtering. However, for certain wireless communications devices (e.g., devices that communicate with low RF bandwidths of 5 MHz to 20 MHz), increasing the sampling frequency for the DAC may affect the power consumption and/or complexity of the device. Thus, increasing the sampling frequency for the DAC may not be available to certain devices that communicate with low RF bandwidths (e.g., 5 MHz to 20 MHz), such as Bluetooth devices, wireless local area network (WLAN) devices, and/or Internet-of-Things (IoT) devices. While aspects described herein may be particularly advantageous when implemented in such devices, benefits of implementing such aspects may be realized in other devices as well.

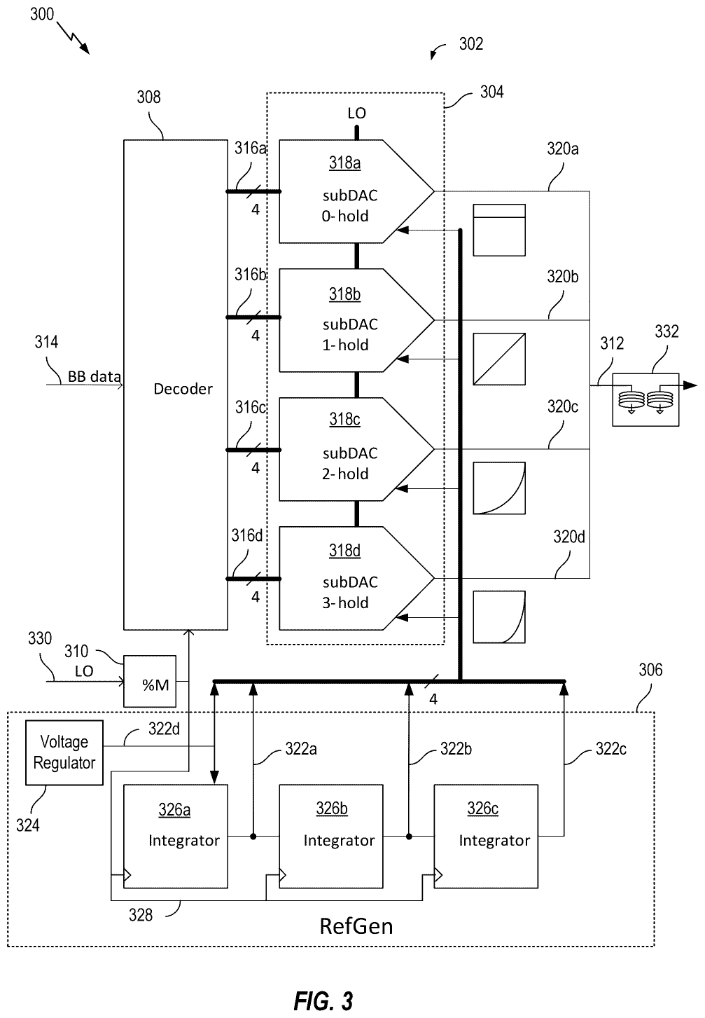

Aspects described herein may overcome the aforementioned technical problem(s), for example, by providing a digital transmitter that uses a multi-order hold DAC to suppress or eliminate image(s) in the output signal of the digital transmitter. As a general example, the multi-order hold DAC may output an RF signal as multiple components of a model (e.g., a Taylor series model, Newtonian series model, Chebyshev polynomials, or the like) for the envelope waveform of the RF signal, as further described herein with respect to FIGS. 3-5. For example, the multi-order hold DAC may include multiple DACs, where each of the DACs may provide the output for a component of the model (e.g., Taylor series model) for the envelope waveform of the RF signal. A voltage generator may feed one or more time-varying reference voltages to the multi-order hold DAC. The time-varying reference voltage may form a periodic waveform that varies the voltage across a symbol period based on a component of the model (e.g., Taylor series model), such as a constant component, a linear component (e.g., a saw tooth waveform), quadratic component, and/or cubic component. The multi-order hold DAC may be driven at a sampling frequency that is less than or equal to the carrier frequency.

Certain architectures for a digital transmitter described herein may provide various beneficial technical effects and/or advantages. The architectures for a digital transmitter may enable improved performance, such as reduced power consumption, complexities, and/or elimination or suppression of image(s) in the output signal. As the power consumption of the digital transmitter can be proportional to the sampling frequency, the reduced power consumption may be attributable to the digital transmitter being driven at a low sampling frequency (e.g., 80 MHz), which may be lower than the carrier frequency. In certain aspects, the digital transmitter may reduce the complexity of the circuitry, for example, by eliminating certain components in the transmit chain, such as mixer(s), amplifier(s), etc. The image(s) of the DAC may be eliminated or suppressed, for example, by forming the RF signal based on the model (e.g., Taylor series model) for the envelope waveform of the RF signal as further described herein. The components of the model (e.g., Taylor series model) for the RF signal may enable the digital transmitter to output an accurate representation of the RF signaling with reduced error(s) that contribute to the image(s).

### Example Wireless Communications System

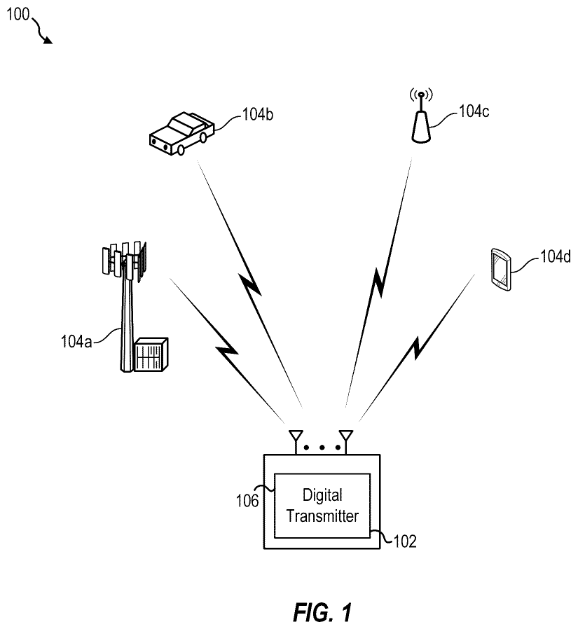

FIG. 1 illustrates an example wireless communications system 100 in which aspects of the present disclosure may be performed. For example, the wireless communications system 100 may include a wireless wide area network (WWAN) and/or a wireless local area network (WLAN). A WWAN may include a New Radio (NR) system (e.g., a Fifth Generation (5G) NR network), an Evolved Universal Terrestrial Radio Access (E-UTRA) system (e.g., a Fourth Generation (4G) network), a Universal Mobile Telecommunications System (UMTS) (e.g., a Second Generation (2G) or Third Generation (3G) network), a code division multiple access (CDMA) system (e.g., a 2G/3G network), any future WWAN system, or any combination thereof. A WLAN may include a wireless network configured for communications according to an Institute of Electrical and Electronics Engineers (IEEE) standard such as one or more of the 802.11 standards, etc. In some cases, the wireless communications system 100 may include a device-to-device (D2D) communications network or a short-range communications system, such as Bluetooth communications or near field communications (NFC).

As illustrated in FIG. 1, the wireless communications system 100 may include a first wireless device 102 communicating with any of various second wireless devices 104a-d (hereinafter “the second wireless device 104”) via any of various radio access technologies (RATs), where a wireless device may refer to a wireless communications device. The RATs may include, for example, WWAN communications (e.g., E-UTRA and/or 5G NR), WLAN communications (e.g., IEEE 802.11), vehicle-to-everything (V2X) communications, non-terrestrial network (NTN) communications, short-range communications (e.g., Bluetooth), etc.

The first wireless device 102 may include any of various wireless communications devices including a user equipment (UE), a base station, a wireless station, an access point, customer-premises equipment (CPE), etc. In certain aspects, the first wireless device 102 includes a digital transmitter 106 that outputs an RF signal with reduced power consumption and image suppression and/or elimination, in accordance with aspects of the present disclosure.

The second wireless device 104 may include, for example, a base station 104a, a vehicle 104b, an access point (AP) 104c, and/or a UE 104d. Further, the wireless communications systems 100 may include terrestrial aspects, such as ground-based network entities (e.g., the base station 104a and/or access point 104c), and/or non-terrestrial aspects, such as a spaceborne platform and/or an aerial platform, which may include network entities on-board (e.g., one or more base stations) capable of communicating with other network elements (e.g., terrestrial base stations) and/or user equipment.

The base station 104a may generally include: a NodeB, enhanced NodeB (eNB), next generation enhanced NodeB (ng-eNB), next generation NodeB (gNB or gNodeB), access point, base transceiver station, radio base station, radio transceiver, transceiver function, transmission reception point, and/or others. The base station 104a may provide communications coverage for a respective geographic coverage area, which may sometimes be referred to as a cell, and which may overlap in some cases (e.g., a small cell may have a coverage area that overlaps the coverage area of a macro cell). A base station may, for example, provide communications coverage for a macro cell (covering relatively large geographic area), a pico cell (covering relatively smaller geographic area, such as a sports stadium), a femto cell (relatively smaller geographic area (e.g., a home)), and/or other types of cells.

The first wireless device 102 and/or the UE 104d may generally include: a cellular phone, smart phone, session initiation protocol (SIP) phone, laptop, personal digital assistant (PDA), satellite radio, global positioning system, multimedia device, video device, digital audio player, camera, game console, tablet, smart device, wearable device, vehicle, electric meter, gas pump, large or small kitchen appliance, healthcare device, implant, sensor/actuator, display, internet of things (IoT) devices, always on (AON) devices, edge processing devices, or other similar devices. A UE may also be referred to more generally as a mobile device, a wireless device, a wireless communications device, a wireless station (STA), a mobile station, a subscriber station, a mobile subscriber station, a mobile unit, a subscriber unit, a wireless unit, a remote unit, a remote device, an access terminal, a mobile terminal, a wireless terminal, a remote terminal, a handset, and other terms.

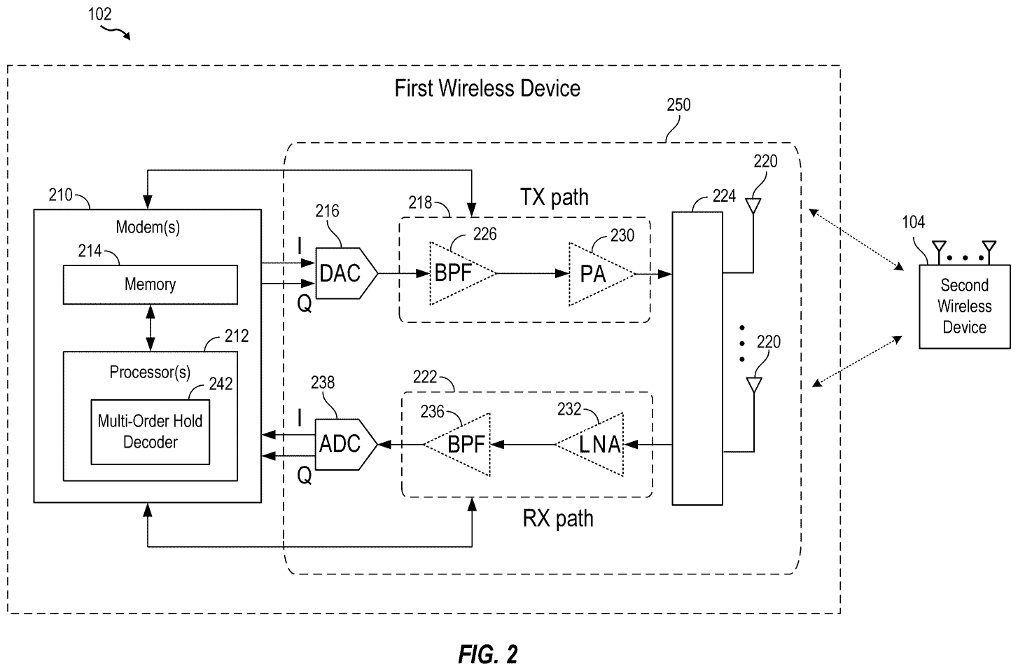

FIG. 2 illustrates example components of the first wireless device 102, which may be used to communicate with any of the second wireless devices 104.

The first wireless device 102 may be, or may include, a chip, system on chip (SoC), system in package (SiP), chipset, package, device that includes one or more modems 210 (hereinafter “the modem 210”). In some cases, the modem 210 may include, for example, any of a WWAN modem (e.g., a modem configured to communicate via E-UTRA 5G NR, and/or any future WWAN communications standards), a WLAN modem (e.g., a modem configured to communicate via IEEE 802.11 standards), a Bluetooth modem, a NTN modem, etc. In certain aspects, the first wireless device 102 also includes one or more RF transceivers (hereinafter “the RF transceiver 250”), such as a digital transceiver, for example that includes the digital transmitter 106. In some cases, the RF transceiver 250 may be referred to as an RF front end (RFFE). In some aspects, the modem 210 further includes one or more processors, processing blocks or processing elements (hereinafter “the processor 212”) and one or more memory blocks or elements (hereinafter “the memory 214”). In some cases, the processor 212 may implement and/or include a multi-order hold decoder 242 that converts a digital baseband signal to certain components (e.g., Taylor series components) for a model of the RF waveform, for example, as further described herein with respect to FIG. 3. In certain aspects, the processor 212 and/or the memory 214 are implemented external or otherwise separate from the modem 210.

In certain aspects, the processor 212 may process any of certain protocol stack layers associated with a radio access technology (RAT). For example, the processor 212 may process any of an application layer, packet layer, WLAN protocol stack layers (e.g., a link or a medium access control (MAC) layer), and/or WWAN protocol stack layers (e.g., a radio resource control (RRC) layer, a packet data convergence protocol (PDCP) layer, a radio link control (RLC) layer, and a MAC layer).

The modem 210 may generally be configured to implement a physical (PHY) layer. For example, the modem 210 may be configured to modulate packets and to output the modulated packets to the RF transceiver 250 for transmission over a wireless medium. The modem 210 is similarly configured to obtain modulated packets received by the RF transceiver 250 and to demodulate the packets to provide demodulated packets. In addition to a modulator and a demodulator, the modem 210 may further include digital signal processing (DSP) circuitry, automatic gain control (AGC), a coder, a decoder, a multiplexer, and/or a demultiplexer (not shown).

As an example, while in a transmission mode, the modem 210 may obtain data from a data source, such as an application processor. The data may be provided to a coder, which encodes the data to provide encoded bits. The encoded bits may be mapped to points in a modulation constellation (e.g., using a selected modulation and coding scheme) to provide modulated symbols. The modulated symbols may be mapped, for example, to spatial stream(s) or space-time streams. The modulated symbols may be multiplexed, transformed via an inverse fast Fourier transform (IFFT) block, and subsequently provided to DSP circuitry for transmit windowing and filtering. The digital signals may be provided to a digital-to-analog converter (DAC) 216, such as a multi-order DAC as described herein with respect to FIG. 3. As an example, the multi-order hold decoder 242 may feed the digital signals to the DAC 216, and the digital signals may include certain components for the model of the RF waveform, such as Taylor series components, as further described herein with respect to FIG. 3. In certain aspects involving beamforming, the modulated symbols in the respective spatial streams may be precoded via a steering matrix prior to provision to the IFFT block.

The modem 210 may be coupled to the RF transceiver 250 by a transmit (TX) path 218 (also known as a transmit chain) for transmitting signals via one or more antennas 220 (hereinafter “the antennas 220”) and a receive (RX) path 222 (also known as a receive chain) for receiving signals via the antennas 220. When the TX path 218 and the RX path 222 share the antennas 220, the paths may be coupled to the antennas 220 via an interface 224, which may include any of various suitable RF devices, such as a balun, an antenna tuner, a switch, a duplexer, a diplexer, a multiplexer, and the like. As an example, the modem 210 may output digital in-phase (I) and/or quadrature (Q) baseband signals representative of the respective symbols to the DAC 216, which may output analog signal(s) at an RF carrier frequency as further described herein with respect to FIG. 3. In some examples, all or most of the elements illustrated as being included in the RF transceiver 250 are implemented in a single chip or die. For example, in some configurations, all of the elements of the RF transceiver except the antennas 220 are implemented on a single chip. In some other configurations, the interface 224 or a portion thereof is also omitted from the single chip.

Receiving analog signals at the RF carrier frequency from the DAC 216, the TX path 218 may include a band pass filter (BPF) 226 and a power amplifier (PA) 230. The BPF 226 filters the RF carrier signal received from the DAC 216, and the PA 230 may convert the RF signal to a high power signal before transmission by the antennas 220. The antennas 220 may emit RF signals, which may be received at the second wireless device 104. In some cases, the DAC 216 may feed the analog signals directly to the interface 224 and/or the antennas 220

The RX path 222 may include a low noise amplifier (LNA) 232 and a bandpass filter (BPF) 236. RF signals received via the antennas 220 (e.g., from the second wireless device 104) may be amplified by the LNA 232, and the signals output by the LNA 232 may be filtered by the BPF 236 before being converted by an analog-to-digital converter (ADC) 238 to digital I or Q signals for digital signal processing. The modem 210 may receive the digital I or Q signals and further process the digital signals, for example, demodulating the digital signals into information.

While in a reception mode, the modem 210 may obtain digitally converted signals via the ADC 238 and RX path 222. As an example, in the modem 210, digital signals may be provided to the DSP circuitry, which is configured to acquire a received signal, for example, by detecting the presence of the signal and estimating the initial timing and frequency offsets. The DSP circuitry is further configured to digitally condition the digital signals, for example, using channel (narrowband) filtering, analog impairment conditioning (such as correcting for I/Q imbalance), and applying digital gain to ultimately obtain a narrowband signal. The output of the DSP circuitry may be fed to the AGC, which is configured to use information extracted from the digital signals, for example, in one or more received training fields, to determine an appropriate gain. The output of the DSP circuitry also may be coupled with the demodulator, which is configured to extract modulated symbols from the signal and, for example, compute the logarithm likelihood ratios (LLRs) for each bit position of each subcarrier in each spatial stream. The demodulator may be coupled with the decoder, which may be configured to process the LLRs to provide decoded bits. The decoded bits from all of the spatial streams may be fed to the demultiplexer for demultiplexing. The demultiplexed bits may be descrambled and provided to a medium access control layer (e.g., the processor 212) for processing, evaluation, or interpretation.

The modem 210 and/or processor 212 may control the transmission of signals via the TX path 218 and/or reception of signals via the RX path 222. In some aspects, the modem 210 and/or processor 212 may be configured to perform various operations, such as those associated with any of the methods described herein. The modem 210 and/or processor 212 may include a microcontroller, a microprocessor, an application processor, a baseband processor, a MAC processor, an artificial intelligence (AI) processor, a digital signal processor (DSP), an application specific integrated circuit (ASIC), a field programmable gate array (FPGA) or other programmable logic device (PLD), discrete gate or transistor logic, discrete hardware components, or any combination thereof. The memory 214 may store data and program codes (e.g., processor-readable instructions) for performing wireless communications as described herein. In some cases, the memory 214 may be external to the modem 210 and/or processor 212 and/or incorporated therein (as illustrated with the memory 214 or being incorporated with the processor 212).

FIG. 2 shows an example transceiver design. It will be appreciated that other transceiver designs or architectures may be applied in connection with aspects of the present disclosure. For example, while examples discussed herein utilize I and Q signals (e.g., quadrature modulation), those of skill in the art will understand that components of the transceiver may be configured to utilize any other suitable modulation, such as polar modulation. As another example, circuit blocks may be arranged differently from the configuration shown in FIG. 2, and/or other circuit blocks not shown in FIG. 2 may be implemented in addition to or instead of the blocks depicted.

### Example Digital Transmitter

Aspects of the present disclosure provide a digital transmitter that uses a multi-order hold DAC to suppress or eliminate image(s) in the RF output of the digital transmitter.

FIG. 3 depicts an example architecture 300 for a digital RF transmitter 302 (hereinafter “the digital transmitter 302,” which may be an example of the digital transmitter 106 of FIG. 1). The digital transmitter 302 may be configured to suppress or eliminate residual image(s) in an output signal and operate at a low sampling frequency, such as a sampling frequency less than or equal to a carrier frequency of an RF signal output at or by the digital transmitter 302. Accordingly, the digital transmitter 302 may enable improved performance, such as reduced power consumption, reduced complexities, and/or image suppression and/or elimination in the output signal.

In this example, the digital transmitter 302 includes a multi-order hold DAC 304 and one or more reference voltage generators 306. In certain aspects, the digital transmitter 302 may further include one or more decoder(s) (hereinafter “the decoder 308”) and/or a frequency divider 310. In certain aspects, the multi-order hold DAC 304 may generate an RF signal at output port(s) 312 and feed the RF signal to a transformer 332, which may be coupled to one or more antennas (not shown), such as the antennas 220 of FIG. 2. The transformer 332 may be coupled between the output port(s) 312 of the multi-order hold DAC 304 and the antenna(s). In certain aspects, the transformer 332 may be an example of the interface 224 of FIG. 2. In some cases, the multi-order hold DAC 304 may feed the RF signal to the antenna(s) (e.g., through the transformer 332) with sufficient power to emit an RF signal via the antenna(s). Thus, the multi-order hold DAC 304 may effectively serve as an amplifier (e.g., a power amplifier) for the RF signal, and the digital transmitter 302 may not employ a separate amplifier.

The decoder 308 may be configured to obtain first information 314 (depicted as baseband (BB) data) representative of a baseband signal and output a plurality of digital components 316a-d of the RF signal based on the first information 314. In certain aspects, one or more digital signals may be or include the digital components 316a-d of the RF signal. The decoder 308 may obtain an oscillating signal 328 from the frequency divider 310 and/or a local oscillator signal 330 to generate the digital signal(s) at an update frequency (e.g., update rate) that matches the carrier frequency or is within a threshold frequency range of the carrier frequency. The oscillating signal 328 may provide the update frequency for the multi-order hold DAC 304, and the decoder 308 may feed the digital signals, to the multi-order hold DAC 304, at the update frequency. The local oscillator signal 330 may be generated by a local oscillator (not shown). In certain cases, the digital transmitter 302 may not employ another local oscillator dedicated for upconversion in a transmit chain, which may reduce the power consumption and/or non-linear effects.

The decoder 308 may convert the first information 314 into multiple digital components 316a-d of an envelope waveform model (e.g., a Taylor series model) for an RF signal output by or at the digital transmitter 302. The decoder 308 may be an example of the multi-order hold decoder 242 depicted in FIG. 2. Generally speaking, the decoder 308 may be implemented in the digital domain of the digital transmitter 302. For example, the decoder 308 may be or include one or more DSP circuits and/or one or more processors (such as the processor 212 and/or modem 210). In certain aspects, the operations of the decoder 308 described herein may be implemented as software components (e.g., processor-readable instructions) that are executed on one or more processors.

The first information 314 may be or include a digital baseband signal, such as digital in-phase baseband signal and/or a digital quadrature baseband signal. In certain cases, the RF signal output by or at the digital transmitter 302 may include baseband signal(s) modulated with an RF carrier. For example, upconversion of the baseband signal to an RF carrier frequency may form the RF signal. The baseband signal may be in a baseband frequency bandwidth that is arranged outside of an RF bandwidth of the RF signal, and may include signals that have been digitally rotated. For example, the frequency of the baseband signal may be less than the RF carrier frequency. The baseband signal may be modulated to carry information (e.g., binary data bits) based on a digital modulation scheme (e.g., phase-shift keying, quadrature amplitude modulation (QAM), or the like). In certain cases, the first information 314 may be or include a digital representation of the RF signal modulated with the baseband signal.

In certain aspects, the envelope waveform of the RF signal may be expressed in the form of a Taylor series as follows:

$$f ( t ) = {\sum }_{h = 0}^{∞} \frac{{f}^{h} ( {t}_{0} ) {( t - {t}_{0} )}^{h}}{h !} \qquad ( 1 )$$

where f(t) is a continuous-time voltage signal for the RF envelope signal output by or at the digital transmitter 302, f^{h}(t₀) is the h-order derivative of f(t) at t₀, and (t-t₀)^{h} is the h-order power function for the time delta. Accordingly, the waveform of the RF envelope signal may be approximated as a partial expansion of the Taylor series, for example, expressed up to a third-order hold as follows:

$$f ( t ) ≅ f ( {t}_{0} ) + {f}^{′} ( {t}_{0} ) ( t - {t}_{0} ) + \frac{{f}^{″} ( {t}_{0} ) {( t - {t}_{0} )}^{2}}{2} + \frac{{f}^{′′′} ( {t}_{0} ) {( t - {t}_{0} )}^{3}}{6} \qquad ( 2 )$$

The partial expansion of Expression (2) provides a sum of a zero-order hold, a first-order hold, a second-order hold, and a third-order hold for the waveform of the RF signal. Note that a partial expansion of a Taylor series model of an RF signal may include any number or combination of h-order holds with respect to Expression (1).

Each of the digital components 316a-d output by the decoder 308 may be or include the h-order derivative component and/or h-order factorial component of the partial expansion. For example, the digital components 316a-d of the decoder 308 may be or include

$$f ( {t}_{0} ) , {f}^{′} ( {t}_{0} ) , \frac{{f}^{″} ( {t}_{0} )}{2} , and \frac{{f}^{′′′} ( {t}_{0} )}{6}$$

of the partial expansion of Expression (2). For example, a digital component of the RF envelope signal may be based on a derivative of an order of a waveform function for the RF envelope signal, and the order may include one or more of a zero order (e.g., a constant), a first order (e.g., a first derivative), a second order (e.g., a second derivative), or a third order (e.g., a third derivative). In certain cases, each of the digital components 316a-d may be or include a bit string having a certain bit length, such as 4 bits or any other suitable length to quantize the certain components for the model. The bit string may be or include a quantized value of the h-order derivative component at a specific instance in time.

In certain aspects, the decoder 308 may output any number and/or combination of digital components for a partial expansion of a Taylor series model for the RF signal. As an example, the decoder 308 may output the zero-order component (e.g., f(t₀)) and the first-order component (f′(t₀)). In some cases, the decoder may output the zero-order component, the first-order component, and the second-order component

$$( e . g . , \frac{{f}^{″} ( {t}_{0} )}{2} ) .$$

In certain cases, the decoder may output the zero-order component and the second-order component.

The multi-order hold DAC 304 may be coupled to the decoder 308. The decoder 308 may feed the digital components 316a-d of the partial expansion of the waveform model to the multi-order hold DAC 304, and then the multi-order hold DAC 304 may convert the digital components into an analog RF signal and output RF signal at the output port(s) 312. The multi-order hold DAC 304 may be configured to output a signal with a carrier frequency in an RF bandwidth. As an example, the RF bandwidth may be arranged in sub-6 GHz frequencies or frequency bands. In some cases, the RF bandwidth may be arranged in frequencies or frequency bands from 410 MHz to 7,125 MHz. In certain aspects, the RF bandwidth may occupy a specific frequency range of 5 to 20 MHz for low bandwidth RF communications, such as narrowband communications, IoT communications, WLAN communications, and/or short-range RF communications (e.g., Bluetooth).

The multi-order hold DAC 304 may include a plurality of DACs 318a-d, where each of the DACs 318a-d (or a subset thereof) may output a signal based on a different h-order hold of the partial expansion of the waveform model as described herein. In certain cases, the DACs 318a-d may be referred to as subDACs (for example, as depicted in FIG. 3), and a subDAC may mean that the corresponding DAC is an element of a multi-order hold DAC. In this example, the multi-order hold DAC 304 includes a first DAC 318a, a second DAC 318b, a third DAC 318c, and a fourth DAC 318d. In some cases, the multi-order hold DAC 304 may include two, three, or more DACs with respective h-order hold output signals. As discussed herein with respect to the decoder 308, the multi-order hold DAC 304 may output a signal based on any combination of h-order holds of the partial expansion of the waveform model.

Each of the DACs 318a-d (or a subset thereof) may obtain, from the decoder, a digital component that corresponds to the signal output by the respective DAC based on the respective h-order hold. For example, the first DAC 318a may obtain the first digital component 316a (e.g., the zero-order component) from the decoder 308 and output the first analog signal 320a based on the zero-order hold. The second DAC 318b may obtain the second digital component 316b (e.g., the first-order component) from the decoder 308 and output a second analog signal 320b based on the first-order hold. The third DAC 318c may obtain a third digital component 316c (e.g., the second-order component) from the decoder 308 and output a third analog signal 320c based on the second-order hold. The fourth DAC 318d may obtain a fourth digital component 316d (e.g., the third-order component) from the decoder 308 and output a fourth analog signal 320d based on the third-order hold.

The reference voltage generator(s) 306 may be coupled to the multi-order hold DAC 304. The reference voltage generator(s) 306 may be configured to feed a reference voltage 322a-d to each of the DACs 318a-d of the multi-order hold DAC 304. Each of the reference voltages 322a-d may correspond to a different h-order power function of the partial expansion of the waveform model, such as a zero-order power function (e.g., (t-t₀)⁰), a first-order power function (e.g., (t-t₀)¹), a second-order power function (e.g., (t-t₀)²), or the like.

The reference voltage generator(s) 306 may include one or more integrator circuits and/or a voltage regulator coupled to the multi-order hold DAC 304. In this example, the reference voltage generator(s) 306 include a voltage regulator 324, a first integrator circuit 326a, a second integrator circuit 326b, and a third integrator circuit 326c. In certain aspects, the voltage regulator 324 may be configured to output a fourth reference voltage 322d (e.g., a constant voltage) over time and feeds the fourth reference voltage 322d to the first DAC 318a corresponding to the zero-order hold of the partial expansion.

The first integrator circuit 326a, the second integrator circuit 326b, and the third integrator circuit 326c may be arranged in a chain or cascade to generate certain h-order power functions of the partial expansion of the waveform model. For example, the first integrator circuit 326a may output and feed a first reference voltage 322a (e.g., corresponding to a linear power function) to the second integrator circuit 326b, and the second integrator circuit 326b may output and feed a second reference voltage 322b (e.g., corresponding to a quadratic power function) to the third integrator circuit 326c, which may output a third reference voltage 322c corresponding to a cubic power function. Note that the cascaded arrangement of the integrator circuits 326a-c is an example of the reference voltage generator(s) 306, and aspects of the present disclosure may be implemented using other types of reference voltage generator(s).

As an example, the reference voltage generator(s) 306 may be configured to output the first reference voltage 322a with a first time-varying voltage across a symbol period. The reference voltage generator(s) 306 may be configured to output the first reference voltage 322a with the first time-varying voltage based at least in part on a power function. The reference voltage generator(s) may be configured to output the first reference voltage 322a with the first time-varying voltage based at least in part on a summation component of a Taylor series representation of the envelope of the signal, such as the respective h-order power function of the partial expansion. The power function may include one or more of a first order power function (e.g., a linear power function), a second order power function (e.g., a quadratic power function), a third order power function (e.g., a cubic power function), a fourth order power function (e.g., a quartic power function), or the like, depending on the size of the partial expansion of the waveform model.

The symbol period may correspond to the symbol duration of the digital modulation scheme used to modulate the baseband signal. The symbol period may be based on the sampling frequency applied to the multi-order hold DAC 304. The sampling frequency may be determined based on the RF carrier, for example, according to the following expression:

$${F}_{s} = \frac{{F}_{c}}{M} \qquad ( 3 )$$

where Fₛ is the sampling frequency; F_{c} is the center frequency of the RF carrier; and M is an integer scaling factor, such that, in certain cases, Fₛ may be at least eight times the symbol rate. Thus, the sampling frequency may be less than or equal to the RF carrier frequency. The time-varying reference voltage(s) may be a periodic waveform having a (e.g., symbol) period of 1/Fₛ. To generate a periodic waveform from each of the integrator circuits 326a-c (or a subset thereof), an oscillating (clock) signal 328 (e.g., a sine wave or square wave) may be fed to each of the integrator circuits 326a-c to trigger a reset of the voltage output at the respective integrator circuit at each cycle of the symbol period. For example, at the rising edge of the oscillating signal, the integrator circuits 326a-c may be reset to a reference potential. The frequency divider 310 may convert a local oscillator signal 330 to the oscillating clock signal 328. For example, the frequency divider 310 may obtain the local oscillator signal 330 and output the oscillating signal 328 at a frequency that is a multiple of the reference frequency of the local oscillator signal 330.

The first integrator circuit 326a may be configured to obtain a first input signal (e.g., the fourth reference voltage 322d) and output the first reference voltage 322a based on the first input signal. The first integrator circuit 326a may feed the first reference voltage 322a to the second DAC 318b. The first integrator circuit 326a may be configured to output the first reference voltage 322a based on an integration of the first input signal over time. The first integrator circuit 326a may be configured to output the first reference voltage 322a with the first time-varying voltage based at least in part on a first power function (e.g., a linear power function).

The second integrator circuit 326b may be configured to obtain a second input signal based on the first reference voltage 322a and output the second reference voltage 322b based on the second input signal. The second input signal may include the signal output at or by the first integrator circuit 326a, such as the first reference voltage 322a. The second integrator circuit 326b may feed the second reference voltage 322b to the third DAC 318c. The second integrator circuit 326b may be configured to output the second reference voltage 322b based on an integration of the second input signal over time. The second integrator circuit 326b may be configured to output the second reference voltage 322b with a second time-varying voltage across the symbol period, for example, based at least in part on a second power function (e.g., a quadratic power function) that is different from the first power function associated with the first integrator circuit 326a. Thus, the first time-varying voltage of the first reference voltage 322a may have a different waveform than the second time varying voltage of the second reference voltage 322b across the symbol period.

The third integrator circuit 326c may be configured to obtain a third input signal based on the second reference voltage 322b and output the third reference voltage 322c based on the third input signal. The third input signal may include the signal output at or by the second integrator circuit 326b. The third integrator circuit 326c may feed the third reference voltage 322c to the fourth DAC 318d. The third integrator circuit 326c may be configured to output the third reference voltage 322c based on an integration of the third input signal over time. The third integrator circuit 326c may be configured to output the third reference voltage 322c with a third time varying voltage across the symbol period based at least in part on a third power function (e.g., a cubic power function) that is different from the first power function associated with the first integrator circuit 326a and the second power function associated with the second integrator circuit 326b.

Each of the DACs 318a-d (or a subset thereof) may obtain separate portion(s) of the partial expansion of the waveform model from the decoder 308 and the reference voltage generator(s) 306, respectively. As described herein, the decoder 308 may supply the h-order derivative component and/or h-order factorial component of the partial expansion, and the reference voltage generator(s) 306 may supply the h-order power function of the partial expansion. Then, each of the DACs 318a-d (or a subset thereof) may effectively scale the respective digital component based on the reference voltage (e.g., the h-order power function) to generate the respective h-order component of the partial expansion of the waveform model. Accordingly, the multi-order hold DAC 304 may operate with a low sampling frequency (e.g., a sampling frequency that is less than or equal to the RF carrier frequency) to enable reduced power consumption and output an RF signal with image suppression and/or elimination.

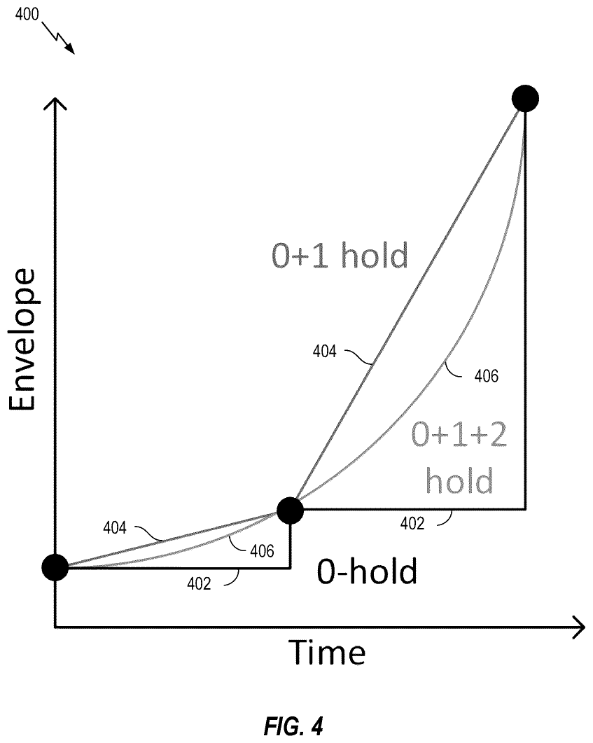

FIG. 4 depicts a graph 400 of example envelopes for output signals of the digital transmitter of FIG. 3. As shown, a first envelope 402 over time is for a first output signal that is formed via a single zero-order hold component of a partial expansion of a waveform model, for example, as described herein with respect to Expression (2). A second envelope 404 over time is for a second output signal that is formed via zero-order hold and first-order hold components of the partial expansion. A third envelope 406 over time is for a third output signal that is formed via a zero-order hold component, a first-order hold component, and a second-order hold component of the partial expansion. The third envelope 406 over time may overlap with the envelope of the waveform model, for example, according to Expression (1).

In general, the differences between first envelope 402 and the third envelope 406 and between the second envelope 404 and the third envelope 406 may be representative of (e.g., proportional to) the energy of image(s) in the output signal of the digital transmitter. Thus, the first output signal may have one or more images, the second output signal may have image(s) with reduced or suppressed energy compared to the image(s) in the first output signal, and the third output signal may lack image(s) or have image(s) with further suppressed energy compared to any images in the second output signal. Accordingly, FIG. 4 demonstrates that the digital transmitter, which employs multiple h-order hold components to form the output signal, may suppress or eliminate image(s) in the output signal.

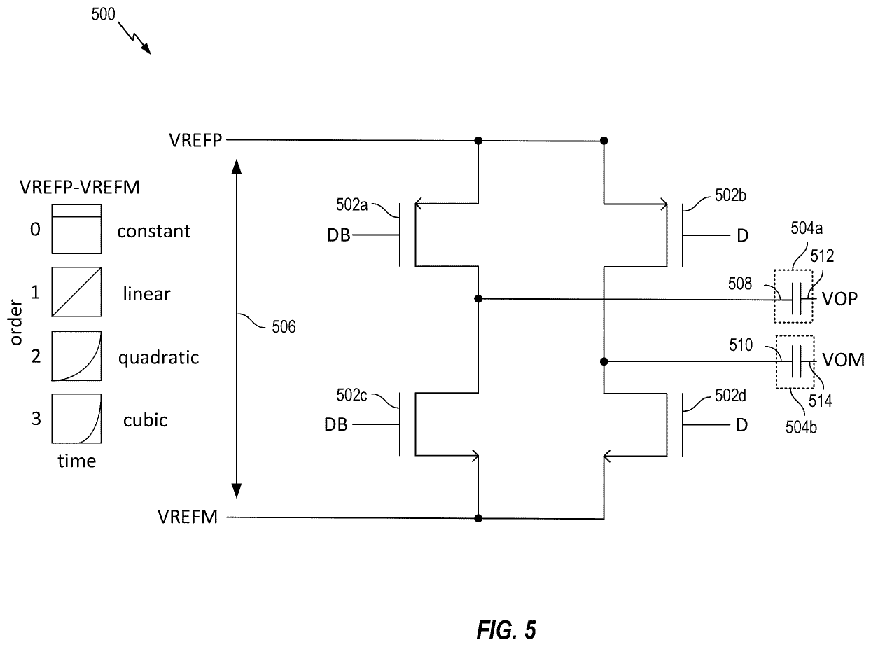

FIG. 5 depicts an example output stage of a DAC 500 of a multi-order hold DAC, for example, as described herein with respect to FIG. 3. The DAC 500 may be an example of any of the DACs 318a-d of FIG. 3. The DAC 500 may use voltage-mode conversion for the output stage, for example, via a voltage-mode capacitor DAC. The DAC 500 may include a plurality of transistors including, for example, a first transistor 502a, a second transistor 502b, a third transistor 502c, and a fourth transistor 502d. The DAC 500 may further include a first capacitive element 504a and a second capacitive element 504b.

The transistors 502a-d may be or include field-effect transistors, such as metal-oxide semiconductor field effect transistors (MOSFETs). The first transistor 502a and the second transistor 502b may be or include p-channel MOSFETs, and the third transistor 502c and the fourth transistor 502d may be or include n-channel MOSFETs. The drain of the first transistor 502a may be coupled to the drain of the third transistor 502c, and the drain of the second transistor 502b may be coupled to the drain of the fourth transistor 502d.

A decoder (e.g., the decoder 308 of FIG. 3) may feed one or more digital signals across the gates of the transistors 502a-d, for example, as described herein with respect to FIG. 3. The digital signal(s) may correspond to a digital component of an RF signal, such as any of the digital components 316a-d of FIG. 3. The digital signal(s) may be updated (or transition), for example, at a center frequency of a carrier frequency of an RF signal, such as Fc of Expression (3). In certain aspects, the digital signal(s) may be updated at a frequency in an RF bandwidth. The center frequency may be or include a sub-6 GHz frequency. In certain aspects, the decoder may feed a first digital signal across the gates of the first transistor 502a and the third transistor 502c, and the decoder may feed a second digital signal across the gates of the second transistor 502b and the fourth transistor 502d. The first digital signal may represent a first voltage, and the second digital signal may represent a second voltage, such that the difference between the first voltage and the second voltage form the amplitude of the RF signal, which may be scaled by a reference voltage. The digital component may correspond to the respective h-order component of the partial expansion.

A reference voltage generator (e.g., the reference voltage generator(s) 306 of FIG. 3) may feed a reference voltage 506 across (i) the source of the first transistor 502a and the source of the third transistor 502c, and across (ii) the source of the second transistor 502b and the source of the fourth transistor 502d. In certain aspects, the reference voltage 506 may have a time-varying waveform, for example, as described herein with respect to FIG. 3. As an example, the reference voltage 506 may have a time-varying waveform based on a linear power function, a quadratic power function, a cubic power function, or the like. The reference voltage 506 may effectively scale the output of the DAC 500.

The first capacitive element 504a has a first terminal 508 coupled between the drains of the first transistor 502a and the third transistor 502c, and the second capacitive element 504b has a second terminal 510 coupled between the drains of the second transistor 502b and the fourth transistor 502d. An output signal of the DAC 500 may be formed across a third terminal 512 of the first capacitive element 504a and a fourth terminal 514 of the second capacitive element 504b. Each of the capacitive elements 504a, 504b may be or include one or more of a capacitor, a tantalum capacitor, aluminum capacitor, ceramic capacitor, a varactor, a metal-insulator-metal (MIM) capacitor, a metal-oxide-metal (MOM) capacitor, a metal-oxide-semiconductor (MOS) capacitor, a metal fringe capacitor, a trench capacitor, a junction capacitance of a diode or transistor, or the like.

Accordingly, the digital transmitter architecture described herein may output an RF signal with reduced power consumption, for example, due to the multi-order hold DAC operating at a low sampling frequency that is less than or equal to the RF carrier frequency. In certain aspects, the digital transmitter architecture may enable elimination and/or suppression of any images in the RF output.

### Example Operations of a Digital Transmitter

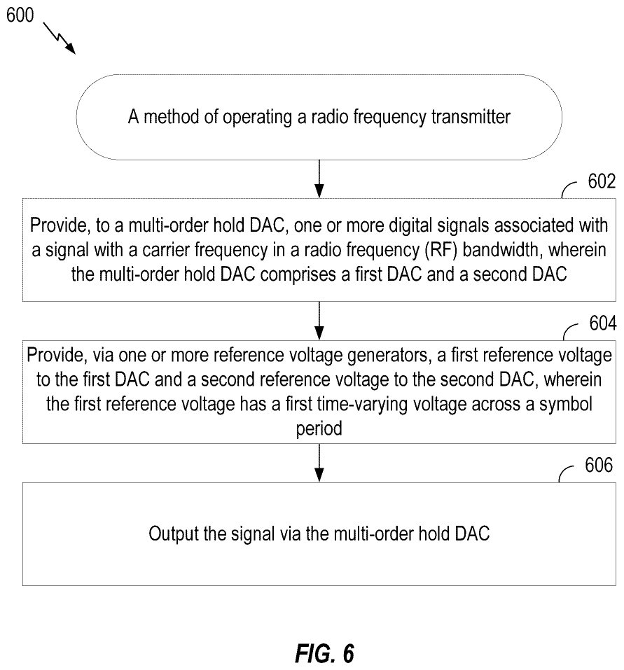

FIG. 6 illustrates an example method 600 for operating a radio frequency (RF) transmitter. The method 600 may be performed, for example, by a digital RF transmitter (e.g., the digital transmitter 302 and/or the first wireless device 102 in the wireless communications system 100).

The method 600 may optionally begin at block 602, where the digital transmitter may provide, to a multi-order hold DAC, one or more digital signals associated with a signal with a carrier frequency in an RF bandwidth. In certain aspects, the multi-order hold DAC comprises a first DAC and a second DAC, for example, as described herein with respect to FIG. 3.

At block 604, the digital transmitter may provide, via one or more reference voltage generators, a first reference voltage to the first DAC and a second reference voltage to the second DAC. The first reference voltage may have a first time-varying voltage across a symbol period, for example, as described herein with respect to FIG. 3.

At block 606, the digital transmitter may output the signal via the multi-order hold DAC. The signal may indicate (or carry) any of various information, such as data and/or control information. In some cases, the signal may indicate (or carry) one or more packets or data blocks.

To provide the first reference voltage, the digital transmitter may provide, to the first DAC, the first reference voltage with the first time-varying voltage based at least in part on a power function. In certain aspects, the power function comprises one or more of a first order power function, a second order power function, or a third order power function. To provide the first reference voltage and the second reference voltage, the digital transmitter may provide, to the first DAC, the first reference voltage with the first time-varying voltage based at least in part on a first power function; and provide, to the first DAC, the second reference voltage with a second time-varying voltage across the symbol period based at least in part on a second power function that is different from the first power function. To provide the second reference voltage, the digital transmitter may provide, to the second DAC, the second reference voltage with a second time-varying voltage across the symbol period, and wherein the first time-varying voltage has a different waveform than the second time-varying voltage across the symbol period. To provide the first reference voltage, the digital transmitter may provide, to the first DAC, the first reference voltage with the first time-varying voltage based at least in part on a summation component of a Taylor series representation of the signal.

In certain aspects, the one or more reference voltage generators comprise one or more integrator circuits coupled to the multi-order hold DAC. In certain aspects, the one or more integrator circuits comprise: a first integrator circuit; and a second integrator circuit coupled to the first integrator circuit, wherein: the first integrator circuit is configured to: obtain a first input signal; and output the first reference voltage based on the first input signal; and the second integrator circuit is configured to: obtain a second input signal based on the first reference voltage; and output the second reference voltage based on the second input signal. To provide the first reference voltage, the digital transmitter may provide, to the first DAC via the first integrator circuit, the first reference voltage based on an integration of the first input signal over time.

In certain aspects, the first DAC comprises a first transistor coupled to a second transistor; a third transistor coupled to a fourth transistor; a first capacitor having a first terminal coupled between the first transistor and the second transistor; and a second capacitor having a second terminal coupled between the third transistor and the fourth transistor. To provide the first reference voltage, the digital transmitter may provide the first reference voltage, to the first DAC, across (i) the first transistor and the second transistor, and across (ii) the third transistor and the fourth transistor.

In certain aspects, the digital transmitter may obtain first information representative of a baseband signal, and to provide the one or more digital signals, the digital transmitter may provide, to the multi-order hold DAC, the one or more digital signals based on the first information. In certain aspects, the baseband signal is in a baseband frequency bandwidth that is arranged outside of the RF bandwidth.

To provide the one or more digital signals comprises, the digital transmitter may provide a first digital component of the signal to the first DAC; and provide a second digital component of the signal to the second DAC. In certain aspects, the first digital component is based on a derivative of an order of a waveform function for an envelope of the signal. In certain aspects, the order comprises one or more of a zero order, a first order, a second order, or a third order.

In certain aspects, the digital transmitter may output the signal via an antenna coupled to the multi-order hold DAC. In certain aspects, a transmitter may be coupled between the antenna and the multi-order hold DAC. For example, the digital transmitter may transmit the signal to another wireless communication device (e.g., any of the second wireless devices 104 depicted in FIG. 1) via the antenna.

Aspects of the present disclosure may be applied to any of various wireless communications devices that may output RF signals described herein.

Various components of a wireless communications device and/or RF transmitter may provide means for performing the method 600 described with respect to FIG. 6, or any aspect related to operations described herein. For example, means for transmitting, sending, or outputting for transmission may include the TX path 218 and/or antenna(s) 220 of the first wireless device 102 illustrated in FIG. 2. Means for providing and/or outputting may include one or more decoders (e.g., the decoder 308), one or more DACs (e.g., the multi-order hold DAC 304, any of the DACs 318a-d, and/or the DAC 500), one or more reference voltage generators (e.g., the reference voltage generator(s) 306), and/or one or more processors, such as the modem 210 and/or processor 212 depicted in FIG. 2.

### Example Aspects

Implementation examples are described in the following numbered clauses:

Aspect 1: A radio frequency (RF) transmitter, comprising: a multi-order hold digital-to-analog converter (DAC) configured to output a signal with a carrier frequency in an RF bandwidth, the multi-order hold DAC comprising: a first DAC and a second DAC; and one or more reference voltage generators coupled to the multi-order hold DAC, wherein the one or more reference voltage generators are configured to feed a first reference voltage to the first DAC and feed a second reference voltage to the second DAC, and wherein the one or more reference voltage generators are configured to output the first reference voltage with a first time-varying voltage across a symbol period.

Aspect 2: The RF transmitter of Aspect 1, wherein the one or more reference voltage generators are configured to output the first reference voltage with the first time-varying voltage based at least in part on a power function.

Aspect 3: The RF transmitter of Aspect 2, wherein the power function comprises one or more of a first order power function, a second order power function, or a third order power function.

Aspect 4: The RF transmitter according to any of Aspects 1-3, wherein the one or more reference voltage generators are configured to: output the first reference voltage with the first time-varying voltage based at least in part on a first power function; and output the second reference voltage with a second time-varying voltage across the symbol period based at least in part on a second power function that is different from the first power function.

Aspect 5: The RF transmitter according to any of Aspects 1-4, wherein the one or more reference voltage generators are configured to output the second reference voltage with a second time-varying voltage across the symbol period, and wherein the first time-varying voltage has a different waveform than the second time-varying voltage across the symbol period.

Aspect 6: The RF transmitter according to any of Aspects 1-5, wherein the one or more reference voltage generators are configured to output the first reference voltage with the first time-varying voltage based at least in part on a summation component of a Taylor series representation of an envelope of the signal.

Aspect 7: The RF transmitter according to any of Aspects 1-6, wherein the one or more reference voltage generators comprise one or more integrator circuits coupled to the multi-order hold DAC.

Aspect 8: The RF transmitter of Aspect 7, wherein one or more integrator circuits comprise: a first integrator circuit; and a second integrator circuit coupled to the first integrator circuit, wherein: the first integrator circuit is configured to: obtain a first input signal; and output the first reference voltage based on the first input signal; and the second integrator circuit is configured to: obtain a second input signal based on the first reference voltage; and output the second reference voltage based on the second input signal.

Aspect 9: The RF transmitter of Aspect 8, wherein the first integrator circuit is configured to output the first reference voltage based on an integration of the first input signal over time.

Aspect 10: The RF transmitter according to any of Aspects 1-9, wherein: the first DAC comprises: a first transistor coupled to a second transistor; a third transistor coupled to a fourth transistor; a first capacitor having a first terminal coupled between the first transistor and the second transistor; and a second capacitor having a second terminal coupled between the third transistor and the fourth transistor; and the one or more reference voltage generators are configured to feed the first reference voltage across (i) the first transistor and the second transistor, and across (ii) the third transistor and the fourth transistor.

Aspect 11: The RF transmitter according to any of Aspects 1-10, further comprising one or more decoders coupled to the multi-order hold DAC, wherein the one or more decoders are configured to: obtain first information representative of a baseband signal; and output, to the multi-order hold DAC, a plurality of digital components of the signal based on the first information.

Aspect 12: The RF transmitter of Aspect 11, wherein the baseband signal is in a baseband frequency bandwidth that is arranged outside of the RF bandwidth.

Aspect 13: The RF transmitter of Aspect 11 or 12, wherein the one or more decoders are configured to: output a first digital component of the signal to the first DAC; and output a second digital component of the signal to the second DAC.

Aspect 14: The RF transmitter of Aspect 13, wherein the first digital component is based on a derivative of an order of waveform function for an envelope the signal.

Aspect 15: The RF transmitter of Aspect 14, wherein the order comprises one or more of a zero order, a first order, a second order, or a third order.

Aspect 16: The RF transmitter according to any of Aspects 1-15, further comprising an antenna coupled to the multi-order hold DAC, wherein the multi-order hold DAC is configured to output the signal to the antenna.

Aspect 17: A method of operating a radio frequency (RF) transmitter, comprising: providing, to a multi-order hold DAC, one or more digital signals associated with a signal with a carrier frequency in an RF bandwidth, wherein the multi-order hold DAC comprises a first DAC and a second DAC; providing, via one or more reference voltage generators, a first reference voltage to the first DAC and a second reference voltage to the second DAC, wherein the first reference voltage has a first time-varying voltage across a symbol period; and outputting the signal via the multi-order hold DAC.

Aspect 18: The method of Aspect 17, wherein providing the first reference voltage comprises providing, to the first DAC, the first reference voltage with the first time-varying voltage based at least in part on a power function.

Aspect 19: The method of Aspect 18, wherein the power function comprises one or more of a first order power function, a second order power function, or a third order power function.

Aspect 20: The method according to any of Aspects 17-19, wherein providing the first reference voltage and the second reference voltage comprises: providing, to the first DAC, the first reference voltage with the first time-varying voltage based at least in part on a first power function; and providing, to the first DAC, the second reference voltage with a second time-varying voltage across the symbol period based at least in part on a second power function that is different from the first power function.

Aspect 21: The method according to any of Aspects 17-20, wherein providing the second reference voltage comprises providing, to the second DAC, the second reference voltage with a second time-varying voltage across the symbol period, and wherein the first time-varying voltage has a different waveform than the second time- varying voltage across the symbol period.

Aspect 22: The method according to any of Aspects 17-21, wherein providing the first reference voltage comprises providing, to the first DAC, the first reference voltage with the first time-varying voltage based at least in part on a summation component of a Taylor series representation of an envelope of the signal.

Aspect 23: The method according to any of Aspects 17-22, wherein the one or more reference voltage generators comprise one or more integrator circuits coupled to the multi-order hold DAC.

Aspect 24: The method of Aspect 23, wherein one or more integrator circuits comprise: a first integrator circuit; and a second integrator circuit coupled to the first integrator circuit, wherein: the first integrator circuit is configured to: obtain a first input signal; and output the first reference voltage based on the first input signal; and the second integrator circuit is configured to: obtain a second input signal based on the first reference voltage; and output the second reference voltage based on the second input signal.

Aspect 25: The method of Aspect 24, wherein providing the first reference voltage comprises providing, to the first DAC, the first reference voltage based on an integration of the first input signal over time.

Aspect 26: The method according to any of Aspects 17-25, wherein: the first DAC comprises: a first transistor coupled to a second transistor; a third transistor coupled to a fourth transistor; a first capacitor having a first terminal coupled between the first transistor and the second transistor; and a second capacitor having a second terminal coupled between the third transistor and the fourth transistor; and wherein providing the first reference voltage comprises providing the first reference voltage, to the first DAC, across (i) the first transistor and the second transistor, and across (ii) the third transistor and the fourth transistor.

Aspect 27: The method according to any of Aspects 17-26, further comprising: obtaining first information representative of a baseband signal, and wherein providing the one or more digital signals comprises providing, to the multi-order hold DAC, the one or more digital signals based on the first information.

Aspect 28: The method of Aspect 27, wherein the baseband signal is in a baseband frequency bandwidth that is arranged outside of the RF bandwidth.

Aspect 29: The method of Aspect 27 or 28, wherein providing the one or more digital signals comprises: providing a first digital component of the signal to the first DAC; and providing a second digital component of the signal to the second DAC.

Aspect 30: The method of Aspect 29, wherein the first digital component is based on a derivative of an order of waveform function for an envelope of the signal.

Aspect 31: The method of Aspect 30, wherein the order comprises one or more of a zero order, a first order, a second order, or a third order.

Aspect 32: The method according to any of Aspects 17-31, further comprising outputting the signal via an antenna coupled to the multi-order hold DAC.

Aspect 33: An apparatus, comprising: a memory; and one or more processors configured to perform a method in accordance with any of Aspects 17-32.

Aspect 34: An apparatus, comprising means for performing a method in accordance with any of Aspects 17-32.

Aspect 36: A non-transitory computer-readable medium comprising computer-executable instructions that, when executed by one or more processors of a processing system, cause the processing system to perform a method in accordance with any of Aspects 17-32.

Aspect 37: A computer program product embodied on a computer-readable storage medium comprising code for performing a method in accordance with any of Aspects 17-32.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the general principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various actions may be added, omitted, or combined. Also, features described with respect to some examples may be combined in some other examples. For example, an apparatus may be implemented, or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

The various illustrative logical blocks, modules and circuits described in connection with the present disclosure may be implemented or performed with a microcontroller, a microprocessor, a general-purpose processor, a digital signal processor (DSP), an artificial intelligence (AI) processor, an application specific integrated circuit (ASIC), a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, a system on a chip (SoC), or any other such configuration.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, identifying, mapping, applying, choosing, establishing, and the like.

The methods disclosed herein comprise one or more actions for achieving the methods. The method actions may be interchanged with one another without departing from the scope of the claims. In other words, unless a specific order of actions is specified, the order and/or use of specific actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” The use of a definite article (e.g., “the” or “said”) before an element is not intended to impart a singular meaning (e.g., “one and only one”) on an otherwise plural meaning (e.g., “one or more”) associated with the element unless specifically so stated. Unless specifically stated otherwise, the term “some” refers to one or more. No claim element is to be construed under the provisions of 35 U.S.C. § 112(f) unless the element is expressly recited using the phrase “means for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

1. A radio frequency (RF) transmitter, comprising:
a multi-order hold digital-to-analog converter (DAC) configured to output a signal with a carrier frequency in an RF bandwidth, the multi-order hold DAC comprising: a first DAC and a second DAC; and
one or more reference voltage generators coupled to the multi-order hold DAC, wherein the one or more reference voltage generators are configured to feed a first reference voltage to the first DAC and feed a second reference voltage to the second DAC, and wherein the one or more reference voltage generators are configured to output the first reference voltage with a first time-varying voltage across a symbol period.

2. The RF transmitter of claim 1, wherein the one or more reference voltage generators are configured to output the first reference voltage with the first time-varying voltage based at least in part on a power function.

3. The RF transmitter of claim 2, wherein the power function comprises one or more of a first order power function, a second order power function, or a third order power function.

4. The RF transmitter of claim 1, wherein the one or more reference voltage generators are configured to:
output the first reference voltage with the first time-varying voltage based at least in part on a first power function; and
output the second reference voltage with a second time-varying voltage across the symbol period based at least in part on a second power function that is different from the first power function.

5. The RF transmitter of claim 1, wherein the one or more reference voltage generators are configured to output the second reference voltage with a second time-varying voltage across the symbol period, and wherein the first time-varying voltage has a different waveform than the second time-varying voltage across the symbol period.

6. The RF transmitter of claim 1, wherein the one or more reference voltage generators are configured to output the first reference voltage with the first time-varying voltage based at least in part on a summation component of a Taylor series representation of an envelope of the signal.

7. The RF transmitter of claim 1, wherein the one or more reference voltage generators comprise one or more integrator circuits coupled to the multi-order hold DAC.

8. The RF transmitter of claim 7, wherein one or more integrator circuits comprise:
a first integrator circuit; and
a second integrator circuit coupled to the first integrator circuit, wherein:
the first integrator circuit is configured to: obtain a first input signal; and
output the first reference voltage based on the first input signal; and
the second integrator circuit is configured to: obtain a second input signal based on the first reference voltage; and output the second reference voltage based on the second input signal.

9. The RF transmitter of claim 8, wherein the first integrator circuit is configured to output the first reference voltage based on an integration of the first input signal over time.

10. The RF transmitter of claim 1, wherein:
the first DAC comprises:
a first transistor coupled to a second transistor;
a third transistor coupled to a fourth transistor;
a first capacitor having a first terminal coupled between the first transistor and the second transistor; and
a second capacitor having a second terminal coupled between the third transistor and the fourth transistor; and
the one or more reference voltage generators are configured to feed the first reference voltage across (i) the first transistor and the second transistor, and across (ii) the third transistor and the fourth transistor.

11. The RF transmitter of claim 1, further comprising one or more decoders coupled to the multi-order hold DAC, wherein the one or more decoders are configured to:
obtain first information representative of a baseband signal; and
output, to the multi-order hold DAC, a plurality of digital components of the signal based on the first information.

12. The RF transmitter of claim 11, wherein the baseband signal is in a baseband frequency bandwidth that is arranged outside of the RF bandwidth.

13. The RF transmitter of claim 11, wherein the one or more decoders are configured to:
output a first digital component of the signal to the first DAC; and
output a second digital component of the signal to the second DAC.

14. The RF transmitter of claim 13, wherein the first digital component is based on a derivative of an order of a waveform function for an envelope of the signal.

15. The RF transmitter of claim 14, wherein the order comprises one or more of a zero order, a first order, a second order, or a third order.

16. The RF transmitter of claim 1, further comprising an antenna coupled to the multi-order hold DAC, wherein the multi-order hold DAC is configured to output the signal to the antenna.

17. A method of operating a radio frequency (RF) transmitter, comprising:
providing, to a multi-order hold digital-to-analog converter (DAC), one or more digital signals associated with a signal with a carrier frequency in an RF bandwidth, wherein the multi-order hold DAC comprises a first DAC and a second DAC;
providing, via one or more reference voltage generators, a first reference voltage to the first DAC and a second reference voltage to the second DAC, wherein the first reference voltage has a first time-varying voltage across a symbol period; and
outputting the signal via the multi-order hold DAC.

18. The method of claim 17, wherein providing the first reference voltage comprises providing, to the first DAC, the first reference voltage with the first time-varying voltage based at least in part on a power function.

19. The method of claim 17, wherein providing the first reference voltage and the second reference voltage comprises:
providing, to the first DAC, the first reference voltage with the first time-varying voltage based at least in part on a first power function; and
providing, to the first DAC, the second reference voltage with a second time-varying voltage across the symbol period based at least in part on a second power function that is different from the first power function.

20. The method of claim 17, wherein providing the first reference voltage comprises providing, to the first DAC, the first reference voltage based on an integration of a first input signal over time.
